(19) United States
(12) Patent Application Publication
(10) Pub. No.: US 2026/0255541 A1
(43) Pub. Date: Aug. 27, 2026

(54) SYSTEM AND METHOD FOR COOLING MANAGEMENT

(71) Applicant: Quanta Computer Inc., Taoyuan City (TW)

(72) Inventors: Ching-Chuan LIU, Taoyuan City (TW); Chun-Ching YU, Taoyuan City (TW)

(21) Appl. No.: 19/059,766

(22) Filed: Feb. 21, 2025

(51) Int. Cl. H05K 7/20

(52) U.S. Cl. CPC H05K 7/20281; H05K 7/20272

(57) ABSTRACT

A computing system for cooling management includes a computer chassis and a chassis management module. The computer chassis includes a heat source and a coolant manifold in thermal contact with the heat source. The chassis management module includes one or more processors coupled to a memory having stored thereon machine readable instructions. The machine executable instructions in the memory are executed by at least one of the one or more processors. Via the one or more processors, the computing system detects a cooling status of the computer chassis. The computing system detects a plurality of cooling systems in electronic communication with the chassis management module, and an operating status for each of the plurality of cooling systems. The computing system selects one of the plurality of cooling systems for which the operating status is a ready status as a primary cooling system for providing a coolant to the coolant manifold.

### FIELD OF THE INVENTION

The present invention relates generally to a system and method for cooling management of a computer chassis. More specifically, the present invention relates to a system and method for cooling management that can support multiple liquid-to-liquid cooling systems, multiple liquid-to-air cooling systems, or a mix of at least one liquid-to-liquid cooling system and at least one liquid-to-air cooling system, and that can automatically reconfigure from a primary cooling system to a secondary cooling system should the primary cooling system fail.

### BACKGROUND OF THE INVENTION

Modern information technology (IT) systems often include high performance central processing units (CPUs), graphics processing units (GPUs), network switches, or other similar components. These components typically have an elevated power consumption that results in a correspondingly elevated level of heat generation. Efficient and reliable cooling solutions are therefore crucial for maintaining optimal performance and preventing overheating. Traditional air-cooling systems often prove insufficient for modern IT systems, which typically utilize systems having a liquid coolant to manage heat dissipation. Such liquid coolant systems can come from many different vendors, can have different control interfaces, and can utilize different types of heat exchangers for cooling the liquid coolant. For example, liquid coolant systems can include a liquid-to-air heat exchanger or a liquid-to-liquid heat exchanger, or both. To support the various available liquid cooling systems, IT systems typically require a chassis management unit that is specifically designed to accommodate particular cooling methods and interfaces.

A need exists for a system and method for cooling management that that automatically supports different types of cooling systems, eliminating the need for end users to manually change the cooling management unit or configuration. The system and method should be able to identify the types of liquid coolant systems that are available and ready to provide cooling to an IT system. The system and method should be able to select and configure a coolant system for primary use from those coolant systems that are available and ready. The system and method should also be reconfigurable to select a secondary liquid coolant system should the primary coolant system fail or become inadequate for the cooling needs of the IT system.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a computing system for cooling management includes a computer chassis and a chassis management module. The computer chassis includes a heat source and a coolant manifold. The heat source is in thermal contact with the coolant manifold. The chassis management module includes one or more processors and a memory having stored thereon machine readable instructions. The one or more processors are coupled to the memory. The machine executable instructions in the memory are executed by at least one of the one or more processors. Via the one or more processors, the computing system detects a cooling status of the computer chassis. The computing system detects a plurality of cooling systems in electronic communication with the chassis management module, and an operating status for each of the plurality of cooling systems via the one or more processors. The computing system selects, via the one or more processors, one of the plurality of cooling systems for which the operating status is a ready status as a primary cooling system for providing a coolant to the coolant manifold.

According to certain aspects of the present disclosure, the one or more processors executes the machine executable instructions in the memory to detect a presence of the plurality of cooling systems in electronic communication with the chassis management module and the operating status for each of the plurality of cooling systems via a general purpose input output (GPIO) interface that communicates signals between the chassis management module and each of the plurality of cooling systems.

According to certain aspects of the present disclosure, the machine readable instructions include a communications protocol to select the one of the plurality of cooling systems as the primary cooling system. The communications protocol is a local protocol or a networked protocol.

According to certain aspects of the present disclosure, the machine executable instructions enable fluid communication between the primary cooling system and the coolant manifold. The fluid communication is enabled in response to an open signal for opening at least one valve.

According to certain aspects of the present disclosure, responsive to a change in the cooling status of the computer chassis, or responsive to a change in the operating status of the primary cooling system, the machine executable instructions in the memory are executed by at least one of the one or more processors to select another of the plurality of cooling systems for which the operating status is the ready status as the primary cooling system.

According to certain aspects of the present disclosure, the change in the cooling status of the computer chassis is from a nominal cooling status to a chassis overheating status.

According to certain aspects of the present disclosure, the change in the operating status of the primary cooling system is from the ready status to a not ready status.

According to certain aspects of the present disclosure, the coolant manifold includes a supply inlet to receive coolant from the primary cooling system, a supply outlet to provide the coolant to at least one internal heat exchanger within the computer chassis and in thermal contact with the heat source, a return inlet to receive coolant from the at least one internal heat exchanger, and a return outlet to provide a path to return the coolant to the primary cooling system.

According to certain aspects of the present disclosure, responsive to a failure to detect any of the plurality of cooling systems in electronic communication with the chassis management module, or responsive to a failure to detect any of the plurality of cooling systems for which the operating status is the ready status, the machine executable instructions in the memory are executed by at least one of the one or more processors to generate an alarm. The machine executable instructions are also executed to repeat the detection of the plurality of cooling systems in electronic communication with the chassis management module. The machine executable instructions are further executed to repeat the detection of the operating status for each of the plurality of cooling systems.

According to certain aspects of the present disclosure, the plurality of cooling systems includes multiple cooling systems having a liquid-to-liquid heat exchanger, multiple cooling systems having a liquid-to-air heat exchanger, or a mixture of cooling systems that includes at least one cooling system having a liquid-to-liquid heat exchanger and at least one cooling system having a liquid-to-air heat exchanger.

According to certain aspects of the present disclosure, the chassis management module is disposed within the computer chassis.

According to certain aspects of the present disclosure, a computer-implemented method for cooling management of a heat source within a computer chassis has a coolant manifold in thermal contact with the heat source. The computer chassis is in electronic communication with a chassis management module having one or more processors and a memory having stored thereon machine readable instructions. The one or more processors are coupled to the memory. The machine executable instructions in the memory are executable by at least one of the one or more processors. The method includes detecting, via the one or more processors, a cooling status of the computer chassis. The method also includes detecting a plurality of cooling systems in electronic communication with the chassis management module, and an operating status for each of the plurality of cooling systems via the one or more processors. The method further includes selecting, via the one or more processors, one of the plurality of cooling systems for which the operating status is a ready status as a primary cooling system. The method also includes configuring the primary cooling system for providing a coolant to a coolant manifold of the computer chassis via the one or more processors.

According to certain aspects of the present disclosure, the one or more processors executes the machine executable instructions in the memory to detect a presence of the plurality of cooling systems in electronic communication with the chassis management module and the operating status for each of the plurality of cooling systems via a general purpose input output (GPIO) interface that communicates signals between the chassis management module and each of the plurality of cooling systems.

According to certain aspects of the present disclosure, the machine readable instructions include a communications protocol for selecting the one of the plurality of cooling systems as the primary cooling system. The communications protocol is a local protocol or a networked protocol.

According to certain aspects of the present disclosure, the machine executable instructions include a communications protocol for the configuring the primary cooling system to provide the coolant to coolant manifold. The communications protocol sends an open signal for opening at least one valve.

According to certain aspects of the present disclosure, responsive to a change in the cooling status of the computer chassis, or responsive to a change in the operating status of the primary cooling system, the method selects, via the one or more processors, another of the plurality of cooling systems as the primary cooling system. The selected cooling system has an operating status that is the ready status. The method also configures, via the one or more processors, the primary cooling system for providing the coolant to the coolant manifold.

According to certain aspects of the present disclosure, responsive to a failure to detect any of the plurality of cooling systems in electronic communication with the chassis management module, or responsive to a failure to detect any of the plurality of cooling systems for which the operating status is the ready status, the method generates an alarm via the one or more processors. The method also redetects, via the one or more processors, the plurality of cooling systems in electronic communication with the chassis management module. The method further redetects, via the one or more processors, the operating status for each of the plurality of cooling systems.

According to certain aspects of the present disclosure, a computer-implemented method for cooling management of a heat source within a computer chassis has a coolant manifold in thermal contact with the heat source. The computer chassis is in electronic communication with a chassis management module having one or more processors and a memory having stored thereon machine readable instructions. The one or more processors are coupled to the memory. The machine executable instructions in the memory are executable by at least one of the one or more processors. The method includes detecting, via the one or more processors, a cooling status of the computer chassis. The method also includes detecting, via a general purpose input output (GPIO) interface, a plurality of cooling systems in electronic communication with the chassis management module. The method further includes detecting, via the GPIO interface, a type and an operating status for each of the plurality of cooling systems. The method further includes selecting, via a communications protocol included in the machine readable instructions, one of the plurality of cooling systems for which the operating status is a ready status as a primary cooling system. The communications protocol is a local protocol or a networked protocol. The method also includes configuring, via the communications protocol, the primary cooling system for providing a coolant to a coolant manifold of the computer chassis. The method configures the primary cooling system by sending an open signal for opening at least one valve.

According to certain aspects of the present disclosure, responsive to a change in the cooling status of the computer chassis from a nominal cooling status to a chassis overheating status, or responsive to a change in the operating status of the primary cooling system from the ready status to a not ready status, the method selects, via the communications protocol, another of the plurality of cooling systems as the primary cooling system. The selected cooling system has an operating status that is the ready status. The method also configures, via the communications protocol, the primary cooling system for providing the coolant to the coolant manifold of the computer chassis. The method configures the primary cooling system by sending an open signal for opening at least one valve.

According to certain aspects of the present disclosure, responsive to a failure to detect any of the plurality of cooling systems in electronic communication with the chassis management module, or responsive to a failure to detect any of the plurality of cooling systems for which the operating status is the ready status, the method generates an alarm via the one or more processors. The method also redetects, via the GPIO interface, the plurality of cooling systems in electronic communication with the chassis management module. The method further redetects, via the GPIO interface, the type and the operating status for each of the plurality of cooling systems.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is a schematic diagram of an exemplary cooling management system, according to certain aspects of the present disclosure.

FIG. 2 shows steps of an exemplary method for cooling a computer chassis, according to certain aspects of the present disclosure.

### DETAILED DESCRIPTION

The current invention is a system and method for managing the cooling of a computer chassis. Available cooling systems are identified by type and readiness. One of the available cooling systems is selected to be a primary cooling system to provide coolant for the computer chassis. If the primary cooling system fails or is inadequate to cool the computer chassis, a secondary cooling system is automatically selected from the available cooling systems and reconfigured to be the new primary cooling system.

Various embodiments are described with reference to the attached figures, where like reference numerals are used throughout the figures to designate similar or equivalent elements. Each reference numeral identifies the figure in which the reference numeral first appears based on the first digit (for three-digit reference numerals) or the first two digits (for four-digit reference numerals) corresponding to the figure numeral of the figure. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

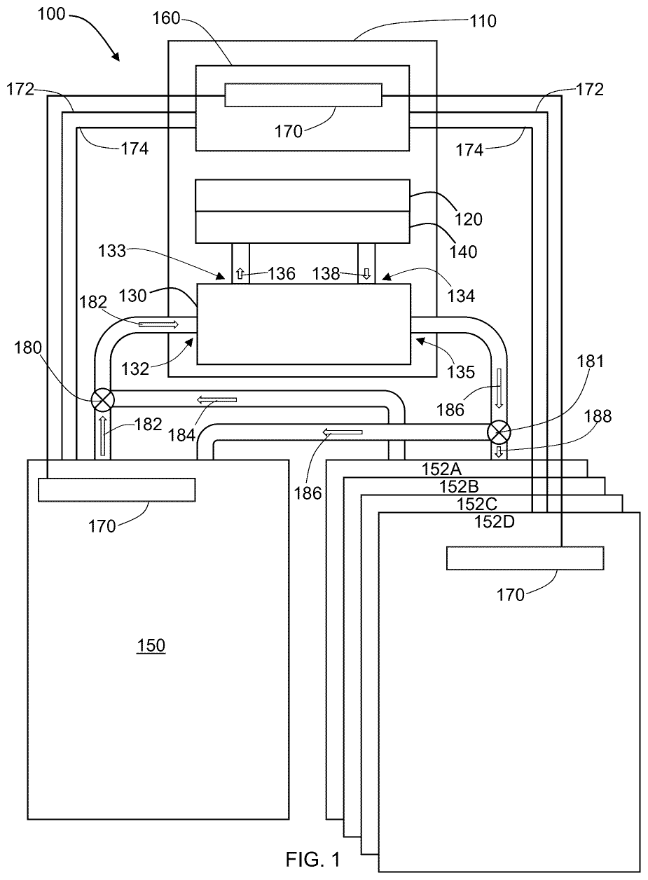

Referring to FIG. 1, an embodiment of a computing system 100 for cooling management includes a computer chassis 110 including a heat source 120 and a coolant manifold 130. The heat source 120 includes one or more of several possible computing components that generate heat. For example, the heat source 120 can include central processing units (CPUs), graphics processing units (GPUs), network switches, other integrated circuit chips, discrete electronic components, or the like. The coolant manifold 130 is in thermal contact with the heat source 120. For example, one or more internal heat exchangers 140 including plates, tubes, and other heat conducting materials are disposed in thermal contact with the heat source 120 and are cooled by liquid coolant from the coolant manifold 130. The heat source 120 and the one or more internal heat exchangers 140 are shown in FIG. 1 as a single heat source 120 and a single internal heat exchanger 140 for clarity of the figure. However, there can be multiple discrete heat sources 120 distributed within the computer chassis 110. Likewise, there can be multiple internal heat exchangers 140 each disposed in contact with one of the individual heat sources 120.

The coolant manifold 130 includes a supply inlet 132 to receive coolant from a primary cooling system 150. The coolant manifold 130 includes a supply outlet 133 to provide the coolant to the one or more internal heat exchangers 140 within the computer chassis 110 and in thermal contact with the heat source 120. The coolant manifold 130 includes a return inlet 134 to receive coolant from the one or more internal heat exchangers 140. The coolant manifold 130 also includes a return outlet 135 to provide a path to return the coolant to the primary cooling system 150. Coolant flows from the supply outlet 133 toward the heat source 120 as shown by the arrows 136. Coolant flows back from the heat source 120, for example, via the internal heat exchangers 140, to the return inlet 134 as shown by the arrows 138.

A chassis management module 160 includes one or more processors and a memory. Machine readable instructions are stored in the memory, and the one or more processors are coupled to the memory. The machine executable instructions in the memory are executed by at least one of the one or more processors to perform various monitoring and management tasks. In one embodiment the chassis management module 160 is disposed within or as a part of the computer chassis 110, as shown in FIG. 1. In other embodiments, the chassis management module 160 is in electrical communication with the computer chassis 110 but physically disposed in a housing separate from the computer chassis 110.

The one or more processors within the chassis management module 160 execute the machine executable instructions stored in the memory to detect a cooling status of the computer chassis 110. The cooling status is determined via communication of the one or more processors with sensors such as thermistors, thermocouples, and the like disposed within the computer chassis 110. The cooling status can be reported as one of several status or alert levels that are descriptive of an internal temperature of at least a portion of the computer chassis 110. The chassis management module 160 also automatically detects the cooling environment available for providing coolant to the computer chassis 110. The cooling environment includes the presence and operating status of a potential plurality of cooling systems 150, 152A, 152B, 152C, and 152D.

For example, in one exemplary status reporting scheme, if the sensed temperatures within the computer chassis 110 are all below a first threshold temperature, the cooling status can be reported to be nominal. Here, the reporting of a nominal cooling status means that the computer chassis is operating at a safe temperature and no interventions or changes are required. In this reporting scheme, if any one of the sensed temperatures within the computer chassis 110 is above the first threshold temperature, the cooling status can be reported to be overheating. Here, the reporting of a chassis overheating status means that the temperature of at least a portion of the computer chassis 110 has exceeded a safe temperature for the at least a portion of the computer chassis 110, and an intervention or change is required to return the cooling status to nominal.

In other reporting schemes, there may be several status levels that are incrementally descriptive of the cooling status of the computer chassis 110. For example, instead of just nominal and overheating, the status levels could include nominal cool, nominal warm, nominal hot, overheating, and overheating emergency.

Referring again to FIG. 1, the chassis management module 160 automatically detects the cooling environment available for providing coolant to the computer chassis 110. The chassis management module 160 automatically adapts to the detected cooling environment by configuring the supply inlet 132 and return outlet 135 of the coolant manifold 130 to respectively receive and return coolant to the selected primary cooling system 150. The chassis management module 160 uses a generalized interface and various communication protocols to detect the presence and operating status of a potential plurality of cooling systems 150, 152A, 152B, 152C, and 152D and to select one of the plurality of cooling systems as the primary cooling system 150. FIG. 1 illustrates five cooling systems 150, 152A, 152B, 152C, and 152D, but this is just one example. Other examples of the plurality of cooling systems can include two, three, four, six, seven, eight, nine, ten, or more cooling systems.

The chassis management module 160 and each of the plurality of cooling systems 150, 152A, 152B, 152C, and 152D includes a general purpose input output (GPIO) interface 170 to transmit and receive signals for detecting the presence of and operating status of the plurality of cooling systems 150, 152A, 152B, 152C, and 152D. Although the GPIO interface 170 is schematically shown only on the top-most cooling system 152D for clarity, each of the cooling systems 152A, 152B, and 152C include the GPIO interface 170. The GPIO interface is a set of general purpose pins (schematically shown as a rectangle for clarity) for communicating signals between devices. The general purpose nature of the GPIO interface facilitates adaptable and flexible communication of signals between the chassis management module 160 and each of the plurality of cooling systems 150, 152A, 152B, 152C, and 152D.

Via the GPIO interface 170, the chassis management module 160 detects the type of cooling system from each of the plurality of cooling systems 150, 152A, 152B, 152C, and 152D. The type of cooling system is detected as being either a cooling system having a liquid-to-liquid heat exchanger or a cooling system having a liquid-to-air heat exchanger. The cooling environment available for providing coolant to the computer chassis 110 includes the plurality of cooling systems 150, 152A, 152B, 152C, and 152D. The plurality of cooling systems 150, 152A, 152B, 152C, and 152D can include multiple cooling systems having a liquid-to-liquid heat exchanger, multiple cooling systems having a liquid-to-air heat exchanger, or a mixture of cooling systems that includes at least one cooling system having a liquid-to-liquid heat exchanger and at least one cooling system having a liquid-to-air heat exchanger.

A liquid-to-liquid heat exchanger typically includes a coolant in a first loop that flows through the heat exchanger and also through the element to be cooled, which in this case is the computer chassis 110. The liquid-to-liquid heat exchanger has a second loop that typically includes water that flows through the heat exchanger and also through an external chiller that cools the water. A liquid-to-air heat exchange similarly has a first loop including coolant that flows through the heat exchanger and through the element to be cooled. However, the liquid-to-air heat exchanger has a second loop that typically includes water that flows through the heat exchanger and also through an external condensing unit that is cooled via airflow.

Via the GPIO interface 170, the chassis management module 160 also detects an operating status for each of the plurality of detected cooling systems 150, 152A, 152B, 152C, and 152D. In an embodiment, the operating status of each of the plurality of detected cooling systems 150, 152A, 152B, 152C, and 152D is a binary status being either ready to provide cooling or not ready to provide cooling. In other embodiments the operating status of each of the plurality of detected cooling systems 150, 152A, 152B, 152C, and 152D includes multiple levels of readiness or may be indicative of a minor or temporary deficiency that prevents a status of ready.

The machine readable instructions executed by the one or more processors of the chassis management module 160 also include at least one communications protocol to select and monitor the primary cooling system 150 from among the plurality of cooling systems 150, 152A, 152B, 152C, and 152D. In an embodiment, the at least one communications protocol also further detects the cooling capacity of each of the plurality of detected cooling systems 150, 152A, 152B, 152C, and 152D.

The at least one communications protocol can be a local protocol or a networked protocol. For example, the at least one communications protocol can be a Modbus®-RTU protocol 172 that facilitates serial communication in an RS-485 standard for selecting, configuring, monitoring, and controlling the primary cooling system 150. In another example, the at least one communications protocol is a Modbus®-TCP protocol 174 that enables networked communication, allowing the chassis management module to select, configure, monitor, and control the primary cooling system 150 over an internet protocol network. In another example, the chassis management module 160 communicates with the detected available plurality of cooling systems 150, 152A, 152B, 152C, and 152D via both the Modbus®-RTU protocol 172 and the Modbus®-TCP protocol 174. Although signal lines for the Modbus®-RTU protocol 172 and the Modbus®-TCP protocol 174 are shown as two separate lines 172 and 174 for clarity in FIG. 1, it should be noted that actual wiring traces or communication lines can share a single common path.

The chassis management module 160 selects the primary cooling system 150 from amongst the detected available plurality of cooling systems 150, 152A, 152B, 152C, and 152D. In an embodiment, this selection is facilitated via user input to an interface on the chassis management module. For example, the chassis management module displays the detected available plurality of cooling systems 150, 152A, 152B, 152C, and 152D for selection by the user. In another embodiment, the chassis management module 160 automatically selects the primary cooling system 150, for example, based on a predetermined set of cooling requirements and selection rules stored within the memory of the chassis management module 160. In another example, the chassis management module 160 automatically selects the primary cooling system 150 based on a predetermined ordered list of the known available plurality of cooling systems 150, 152A, 152B, 152C, and 152D stored within the memory of the chassis management module 160.

Upon selection of the primary cooling system 150, machine readable instructions executed by the one or more processors of the chassis management module 160 enable fluid communication between the primary cooling system 150 and the coolant manifold 130. For example, referring to FIG. 1, fluid communication between the primary cooling system 150 and the coolant manifold 130 is enabled by sending signals to the valves 180 and 181. In FIG. 1, the valve 181 is shown as a single valve for simplicity, but in reality can represent a plurality of valves 181 disposed between the return outlet 135 of the coolant manifold 130 and each of the non-primary cooling systems 152A, 152B, 152C, 152D. The chassis management module 160 sends a signal the valve 180 to allow coolant to flow from the primary cooling system 150 along the arrows 182 while blocking coolant from any of the non-primary cooling systems 152A, 152B, 152C, 152D represented by the arrow 184. The chassis management module 160 also sends a signal to the valve 181 to allow coolant to flow back to the primary cooling system 150 along the arrows 186 while blocking coolant from flowing to any of the non-primary cooling systems 152A, 152B, 152C, 152D along the arrow 188.

During operation of the computer chassis 110, the chassis management module 160 continuously detects the cooling status of the computer chassis 110 as noted above. The chassis management module 160 also monitors the operating status of the primary cooling system 150. If the chassis management module 160 detects a change in the cooling status of the computer chassis 110 from a nominal cooling status to a less than nominal cooling status, the machine executable instructions in the memory of the chassis management module 160 are executed by at least one of the one or more processors to automatically select a new primary cooling system 150. Likewise, if the chassis management module 160 detects a change in the operating status of the primary cooling system 150 from the ready status to a not ready status, the machine executable instructions in the memory of the chassis management module 160 are executed by at least one of the one or more processors to automatically select the new primary cooling system 150. In either circumstance, the automatic selection of the new primary cooling system 150 is automatically made from among the plurality of non-primary cooling systems 152A, 152B, 152C, and 152D. Upon selection of the new primary cooling system 150, signals are sent to the valves 180 and 181 to configure the flow of coolant from the new primary cooling system 150 to the coolant manifold 130.

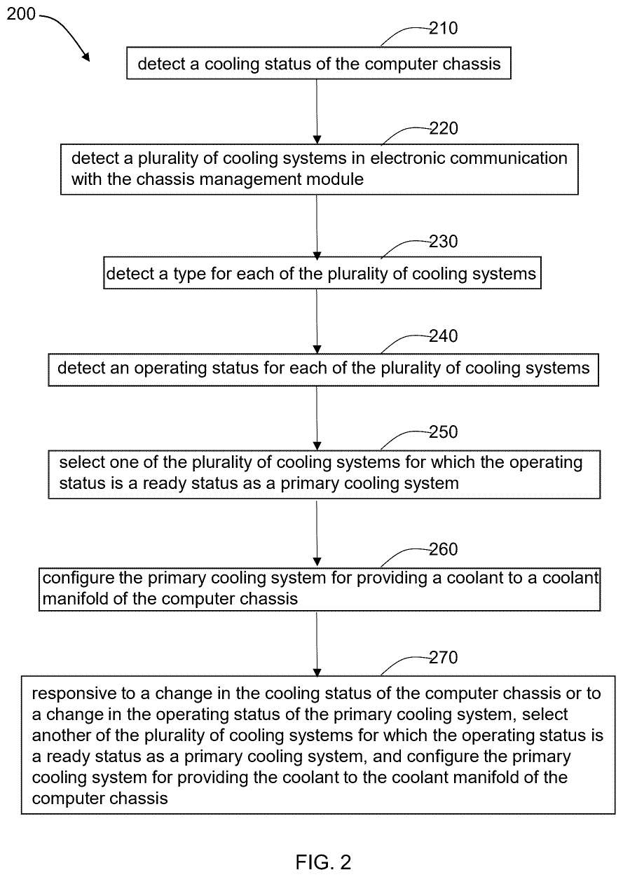

A computing system 100 for cooling management of a computer chassis 110 is described herein. Referring to FIG. 2, a method 200 for cooling management of the computer chassis 110 begins at step 210 where the automatic detection sequence initiates by detecting a cooling status of the computer chassis 110. The cooling status of the computer chassis 110 can be reported as a binary good or bad result, for example, as nominal or overheating. Alternatively, the cooling status of the computer chassis 110 can have a more incremental or nuanced reporting scheme having additional levels of status as described above.

At step 220, the method 200 detects the presence of a plurality of cooling systems 150, 152A-152D (FIG. 1) in electronic communication with the chassis management module 160. This detection is facilitated by the receipt of signals from the plurality of cooling systems 150, 152A-152D by the chassis management module 160 via the GPIO interface 170. In addition, the one or more processors execute the machine executable instructions in the memory of the chassis management module 160 to implement one or both of the Modbus®-RTU protocol 172 and the Modbus®-TCP protocol 174 to communicate with the plurality of cooling systems 150, 152A-152D.

At step 230, the method 200 detects a type for each of the plurality of cooling systems 150, 152A-152D. The type of cooling system is either a liquid-to-liquid cooling system or a liquid-to-air cooling system. The detection of the type of cooling system is facilitated by the receipt of signals from the plurality of cooling systems 150, 152A-152D by the chassis management module 160 via the GPIO interface 170.

At step 240, the method 200 detects an operating status for each of the plurality of cooling systems 150, 152A-152D. The operating status can be reported as a binary good or bad result, for example, as ready or not ready. Alternatively, the operating status for each of the plurality of cooling systems 150, 152A-152D can have a more incremental or nuanced reporting scheme having additional levels of status as described above.

At step 250, the method 200 selects one of the plurality of cooling systems 150, 152A-152D for which the operating status is a ready status to be the primary cooling system 150. The non-primary cooling systems 152A-152D remain in a stand-by state available to be redetected and selected in a later step should problems arise with the primary cooling system 150. Communication between the chassis management module 160 and the primary cooling system 150 is facilitated by one or both of the Modbus® communications protocols 172, 174. Communication through the Modbus®-RTU protocol 172 can include a check of the Modbus® registers and the RS-485 tree. Communication through the Modbus®-TCP protocol 174 can include a check of the Modbus® registers and the link status of the local area network.

At step 260, the method 200 configures the primary cooling system 150 to provide coolant to the coolant manifold 130 of the computer chassis 110. This configuration is facilitated by signals sent to open and/or close valves to allow the selected primary cooling system 150 to supply coolant while preventing the non-primary cooling systems 152A-152D from supplying coolant to the coolant manifold 130 of the computer chassis 110.

The method 200 continues to monitor the cooling status of the computer chassis 110 and the operating status of the primary cooling system 150. At step 270, responsive to a change in the cooling status of the computer chassis 110, or responsive to a change in the operating status of the primary cooling system 150, the method 200 selects a new primary cooling system 150 from amongst the non-primary cooling systems 152A-152D having an operating state as a ready status. In this step, the change in the cooling status of the computer chassis 110 that triggers selection of the new primary cooling system 150 can be from a nominal cooling status to a chassis overheating status. Similarly, the change in the operating status of the primary cooling system 150 that triggers selection of the new primary cooling system 150 can be from a ready status to a not ready status. Still at step 270, the method 200 configures the new primary cooling system 150 to provide coolant t the coolant manifold 130 of the computer chassis 110.

If the method 200 fails to detect any of the plurality of cooling systems 150, 152A-152D in either of the steps 220 or 270 as described above, the method 200 further generates an alarm. The alarm can be sent to a system administrator or other monitoring entity at a data center or other monitoring hub to provide an alert that a human interaction or intervention may be necessary to solve the detection issue. After generating the alarm, the method attempts to redetect the presence of, the type of, and the operating status of each of the plurality of cooling systems 150, 152A-152D.

In an embodiment where selection of the primary cooling system 150 is via a user interface, the method 200 also sends an alarm to alert that a plurality of cooling systems 150, 152A-152D have been detected. This alert allows the user to select the primary cooling system 150 from amongst the plurality of cooling systems 150, 152A-152D.

The disclosed computing system 100 and method 200 can dynamically detect and configure a primary cooling system 150 from amongst the plurality of available cooling systems 150, 152A-152D. This capability ensures optimal cooling performance without requiring manual changes to the chassis management module 160 or primary cooling system 150 configuration, which represents a significant advancement in IT system cooling management. Automatic detection and configuration of the various cooling types enhances the efficiency and reliability of thermal management in high-performance computing environments. Further, adaptability through the GPIO interface, the Modbus®-RTU protocol, and the Modbus®-TCP protocol ensures seamless operation, providing a robust solution to the challenges of modern IT cooling.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A computing system for cooling management, the computing system comprising:
a computer chassis including a heat source and a coolant manifold, the heat source being in thermal contact with the coolant manifold; and
a chassis management module having one or more processors and a memory having stored thereon machine readable instructions, the one or more processors being coupled to the memory, the machine executable instructions in the memory being executed by the one or more processors to
detect, via the one or more processors, a cooling status of the computer chassis,
detect, via the one or more processors, a plurality of cooling systems in electronic communication with the chassis management module;
detect, via the one or more processors, an operating status for each of the plurality of cooling systems; and
select, via the one or more processors, one of the plurality of cooling systems for which the operating status is a ready status as a primary cooling system, the primary cooling system providing a coolant to the coolant manifold.

2. The computing system of claim 1, wherein the one or more processors executes the machine executable instructions in the memory to detect a presence of the plurality of cooling systems in electronic communication with the chassis management module and the operating status for each of the plurality of cooling systems via a general purpose input output (GPIO) interface that communicates signals between the chassis management module and each of the plurality of cooling systems.

3. The computing system of claim 1, wherein the machine readable instructions include a communications protocol to select the one of the plurality of cooling systems as the primary cooling system, the communications protocol being a local protocol or a networked protocol.

4. The computing system of claim 1, wherein the machine executable instructions enable fluid communication between the primary cooling system and the coolant manifold, the fluid communication being enabled in response to an open signal for opening at least one valve.

5. The computing system of claim 1, wherein responsive to a change in the cooling status of the computer chassis, or responsive to a change in the operating status of the primary cooling system, the machine executable instructions in the memory are executed by at least one of the one or more processors to select another of the plurality of cooling systems for which the operating status is the ready status as the primary cooling system.

6. The computing system of claim 5, wherein the change in the cooling status of the computer chassis is from a nominal cooling status to a chassis overheating status.

7. The computing system of claim 5, wherein the change in the operating status of the primary cooling system is from the ready status to a not ready status.

8. The computing system of claim 1, wherein the coolant manifold includes a supply inlet to receive coolant from the primary cooling system, a supply outlet to provide the coolant to at least one internal heat exchanger within the computer chassis and in thermal contact with the heat source, a return inlet to receive coolant from the at least one internal heat exchanger, and a return outlet to provide a path to return the coolant to the primary cooling system.

9. The computing system of claim 1, wherein responsive to a failure to detect any of the plurality of cooling systems in electronic communication with the chassis management module, or responsive to a failure to detect any of the plurality of cooling systems for which the operating status is the ready status, the machine executable instructions in the memory are executed by at least one of the one or more processors to
generate an alarm,
repeat the detection of the plurality of cooling systems in electronic communication with the chassis management module, and
repeat the detection of the operating status for each of the plurality of cooling systems.

10. The computing system of claim 1, wherein the plurality of cooling systems includes multiple cooling systems having a liquid-to-liquid heat exchanger, multiple cooling systems having a liquid-to-air heat exchanger, or a mixture of cooling systems that includes at least one cooling system having a liquid-to-liquid heat exchanger and at least one cooling system having a liquid-to-air heat exchanger.

11. The computing system of claim 1, wherein the chassis management module is disposed within the computer chassis.

12. A computer-implemented method for cooling management of a heat source within a computer chassis having a coolant manifold in thermal contact with the heat source, the computer chassis in electronic communication with a chassis management module having one or more processors and a memory having stored thereon machine readable instructions, the one or more processors being coupled to the memory, the machine executable instructions in the memory being executable by one or more processors, the method comprising:
detecting, via the one or more processors, a cooling status of the computer chassis;
detecting, via the one or more processors, a plurality of cooling systems in electronic communication with the chassis management module;
detecting, via the one or more processors, an operating status for each of the plurality of cooling systems;
selecting, via the one or more processors, one of the plurality of cooling systems for which the operating status is a ready status as a primary cooling system; and
configuring, via the one or more processors, the primary cooling system for providing a coolant to a coolant manifold of the computer chassis.

13. The method of claim 12, wherein the one or more processors executes the machine executable instructions in the memory to detect a presence of the plurality of cooling systems in electronic communication with the chassis management module and the operating status for each of the plurality of cooling systems via a general purpose input output (GPIO) interface that communicates signals between the chassis management module and each of the plurality of cooling systems.

14. The method of claim 12, wherein the machine readable instructions include a communications protocol for the selecting the one of the plurality of cooling systems as the primary cooling system, the communications protocol being a local protocol or a networked protocol.

15. The method of claim 12, wherein the machine executable instructions include a communications protocol for the configuring the primary cooling system to provide the coolant to coolant manifold, the communications protocol sending an open signal for opening at least one valve.

16. The method of claim 12, wherein responsive to a change in the cooling status of the computer chassis, or responsive to a change in the operating status of the primary cooling system,
selecting, via the one or more processors, another of the plurality of cooling systems for which the operating status is the ready status as the primary cooling system, and
configuring, via the one or more processors, the primary cooling system for providing the coolant to the coolant manifold.

17. The method of claim 12, wherein responsive to a failure to detect any of the plurality of cooling systems in electronic communication with the chassis management module, or responsive to a failure to detect any of the plurality of cooling systems for which the operating status is the ready status,
generating, via the one or more processors, an alarm,
redetecting, via the one or more processors, the plurality of cooling systems in electronic communication with the chassis management module, and
redetecting, via the one or more processors, the operating status for each of the plurality of cooling systems.

18. A computer-implemented method for cooling management of a heat source within a computer chassis having a coolant manifold in thermal contact with the heat source, the computer chassis in electronic communication with a chassis management module having one or more processors and a memory having stored thereon machine readable instructions, the one or more processors being coupled to the memory, the machine executable instructions in the memory being executable by at least one of the one or more processors, the method comprising:
detecting, via the one or more processors, a cooling status of the computer chassis;
detecting, via a general purpose input output (GPIO) interface, a plurality of cooling systems in electronic communication with the chassis management module;
detecting, via the GPIO interface, a type for each of the plurality of cooling systems;
detecting, via the GPIO interface, an operating status for each of the plurality of cooling systems;
selecting, via a communications protocol included in the machine readable instructions, one of the plurality of cooling systems for which the operating status is a ready status as a primary cooling system, the communications protocol being a local protocol or a networked protocol; and
configuring, via the communications protocol, the primary cooling system for providing a coolant to a coolant manifold of the computer chassis by sending an open signal for opening at least one valve.

19. The method of claim 18, wherein responsive to a change in the cooling status of the computer chassis from a nominal cooling status to a chassis overheating status, or responsive to a change in the operating status of the primary cooling system from the ready status to a not ready status,
selecting, via the communications protocol, another of the plurality of cooling systems for which the operating status is the ready status as the primary cooling system, and
configuring, via the communications protocol, the primary cooling system for providing the coolant to the coolant manifold of the computer chassis by sending an open signal for opening at least one valve.

20. The method of claim 18, wherein responsive to a failure to detect any of the plurality of cooling systems in electronic communication with the chassis management module, or responsive to a failure to detect any of the plurality of cooling systems for which the operating status is the ready status,
generating, via the one or more processors, an alarm,
redetecting, via the GPIO interface, the plurality of cooling systems in electronic communication with the chassis management module,
redetecting, via the GPIO interface, the type for each of the plurality of cooling systems, and
redetecting, via the GPIO interface, the operating status for each of the plurality of cooling systems.
